(19) United States
(12) Patent Application Publication
(10) Pub. No.: US 2026/0204322 A1
(43) Pub. Date: Jul. 16, 2026

(54) MEMORY DEVICE INCLUDING MICROCONTROLLER AND OPERATING METHOD OF THE MEMORY DEVICE, AND MEMORY SYSTEM

(71) Applicant: SAMSUNG ELECTRONICS CO., LTD., Suwon-si (KR)

(72) Inventors: Jeonggil Choi, Suwon-si (KR); Jungho Song, Suwon-si (KR)

(73) Assignee: SAMSUNG ELECTRONICS CO., LTD., Suwon-si (KR)

(21) Appl. No.: 19/442,557

(22) Filed: Jan. 7, 2026

(30) Foreign Application Priority Data
Jan. 10, 2025 (KR) 10-2025-0004375

(51) Int. Cl. G11C 16/10; G06F 9/30; G11C 16/08

(52) U.S. Cl. CPC G11C 16/102; G06F 9/30101; G11C 16/08

(57) ABSTRACT

A memory device is provided. The memory device includes: a memory cell array including a plurality of non-volatile memory cells; and a control logic circuit including: a system bus; a microcontroller configured to write data into a plurality of special function registers via the system bus; and a parallel controller configured to write parallel data into at least two registers among the plurality of special function registers independently of the system bus.

### CROSS-REFERENCE TO RELATED APPLICATION

This application priority under 35 U.S.C. § 119 to Korean Patent Application No. 10-2025-0004375, filed on January 10, 2025, in the Korean Intellectual Property Office, the disclosure of which is incorporated by reference herein in its entirety.

### BACKGROUND

The present disclosure relates to a memory device, and more particularly, to a memory device including a memory controller and an operating method of the memory device, and a memory system.

To facilitate design, micro controller unit (MCU) systems that are easy to modify design have been introduced into logic circuit design. In contrast to a finite state machine (FSM), an MCU system transmits data through a bus. In this case, the amount of data that can be transmitted during a single cycle is limited by a bus bandwidth.

In NAND flash memory, there may be cases where the amount of data that exceeds a data bus bandwidth is required to be written during the initialization of an operation, execution of a reset command, and execution of a suspend command. However, in the MCU system, the amount of data that can be written at one time is limited by the bus bandwidth so that data are required to be sequentially written. This leads to an increase in processing time and results in a decrease in performance.

### SUMMARY

One or more embodiments provide a method of preventing a decrease in performance during a writing operation of data that exceeds the size of a bus bandwidth by writing data at once into a plurality of special function registers (SFRs) during a single cycle in parallel without going through a system bus.

The technical objectives of the inventive concept are not limited to the aforementioned technical objectives, and other technical objectives not mentioned can be clearly understood by a person skilled in the art from the following description.

According to an aspect of an embodiment, a memory device includes: a memory cell array including a plurality of non-volatile memory cells; and a control logic circuit including: a system bus; a microcontroller configured to write data into a plurality of special function registers via the system bus; and a parallel controller configured to write parallel data into at least two registers among the plurality of special function registers independently of the system bus.

According to another aspect of an embodiment, a memory system includes: a memory controller; and a memory device including: a plurality of non-volatile memory cells; and a control logic circuit. The control logic circuit includes: a system bus; a microcontroller configured to write data into a plurality of special function registers via the system bus; and a parallel controller configured to write parallel data into at least two registers among the plurality of special function registers in parallel with the system bus.

According to another aspect of an embodiment, a control logic includes: a system bus; a plurality of special function register circuits; a microcontroller configured to write data into the plurality of special function register circuits via the system bus; and a parallel controller configured to write parallel data into at least two register circuits among the plurality of special function register circuits independently of the system bus.

According to another aspect of an embodiment, an operating method of a memory device including a memory cell array of a plurality of non-volatile memory cells and a control logic, includes: based on an over-bandwidth event, identifying an operating mode from among a parallel transmission mode and a normal transmission mode; writing data into a plurality of special function registers via a first path of a system bus by using a microcontroller, based on the operating mode being identified as the normal transmission mode; and writing parallel data into at least two registers among the plurality of special function registers via a second path independently of the system bus by using a parallel controller, based on the operating mode being identified as the parallel transmission mode.

### BRIEF DESCRIPTION OF DRAWINGS

The above and other aspects will be more apparent from the following description of embodiments taken in conjunction with the accompanying drawings, in which:

FIG. 1 is a block diagram illustrating a memory system according to an embodiment;

FIG. 2 is a block diagram illustrating a memory device according to an embodiment;

FIG. 3 is a circuit diagram illustrating a memory block according to an embodiment;

FIG. 4 is a perspective view illustrating a cell block according to an embodiment;

FIG. 5 is a block diagram illustrating an example of a control logic according to an embodiment;

FIG. 6 illustrates an example of a special function register (SFR) according to an embodiment;

FIG. 7A illustrates an example of signal transmission between a parallel controller and a parallel receiver according to an embodiment;

FIG. 7B is a block diagram illustrating a parallel receiver according to an embodiment;

FIG. 8 illustrates an example of a signal time line according to an embodiment;

FIG. 9 is a cross-sectional view illustrating a memory device having a B-VNAND structure according to an embodiment; and

FIG. 10 is a block diagram illustrating a solid state drive (SSD) system according to an embodiment.

### DETAILED DESCRIPTION

Hereinafter, embodiments of the inventive concept will be described in detail with reference to the accompanying drawings. The embodiments of the inventive concept are provided to more fully describe the inventive concept to a person having average knowledge in the art. Embodiments described herein are example embodiments, and thus, the present disclosure is not limited thereto, and may be realized in various other forms. Since various modifications and various embodiments are possible, specific embodiments are illustrated in the drawings and described in detail in the detailed description. However, this is not intended to limit the inventive concept to a specific disclosure form, but should be understood to include all modifications, equivalents, or substitutes included in the spirit and technical scope of the inventive concept. Each embodiment provided in the following description is not excluded from being associated with one or more features of another example or another embodiment also provided herein or not provided herein but consistent with the present disclosure. When describing each drawing, similar reference numerals are used to refer to similar components. In the attached drawings, the dimensions of the structures are illustrated enlarged or reduced from the actual size to ensure clarity.

The terminology used in this application is used only to describe particular embodiments and is not intended to limit the inventive concept. Singular expressions include plural expressions unless the context clearly indicates otherwise. In this application, it should be understood that terms such as “include” or “have” are intended to specify the presence of a feature, number, step, operation, component, part, or combination thereof described in the specification, but do not exclude in advance the possibility of the presence or addition of one or more other features, numbers, steps, operations, components, parts, or combinations thereof.

Unless otherwise defined, all terms used herein, including technical or scientific terms, have the same meaning as commonly understood by one of ordinary skill in the art to which this invention belongs. Terms defined in commonly used dictionaries should be interpreted as having a meaning consistent with their meaning in the context of the relevant art, and will not be interpreted in an idealized or overly formal sense, unless expressly defined in this application.

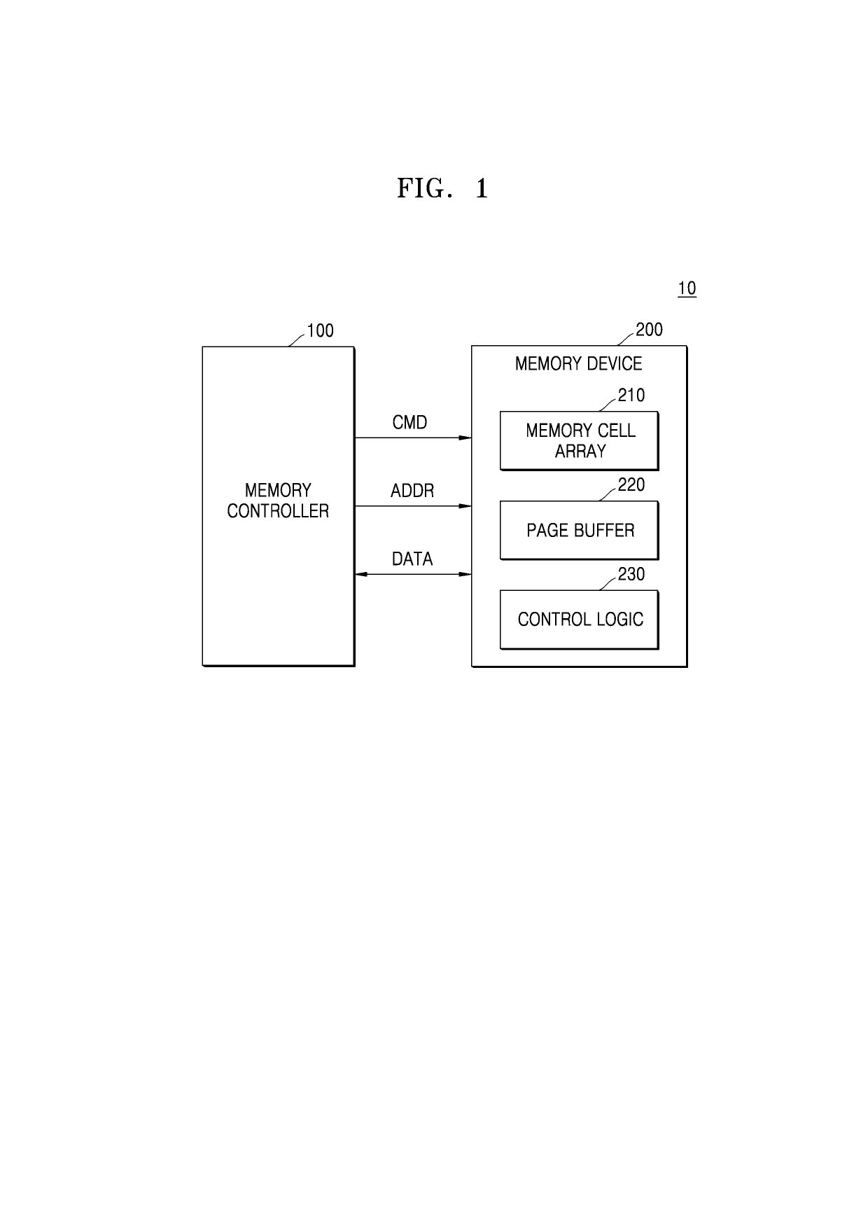

FIG. 1 is a block diagram illustrating a memory system 10 according to an embodiment.

Referring to FIG. 1, the memory system 10 may include a memory controller 100 and a memory device 200, and the memory device 200 may include a memory cell array 210, a page buffer (e.g., page buffer circuit) 220, and a control logic (e.g., control logic circuit) 230.

According to embodiments, the memory controller 100 may control the overall operation of the memory system 10. When power is applied to the memory system 10, the memory controller 100 may execute a firmware (FW). When the memory device 200 is a NAND flash memory device, the memory controller 100 may execute a firmware such as a flash translation layer (FTL) for controlling communication between an external host and the memory system 10. For example, the memory controller 100 may receive data and a logical block address (LBA) from the host, and may connect the LBA to a physical block address (PBA). The PBA may represent an address of a memory cell in which the data may be stored, among memory cells included in the memory device 200.

According to embodiments, the memory controller 100 may control the memory device 200 so as to read the data stored in the memory device 200 or to program the data into the memory device 200 in response to a reading/writing request from the host. Specifically, the memory controller 100 may control a programming operation, a reading operation, and an erasing operation, and the like of the memory device 200 by providing an address ADDR, a command CMD, a control signal CTRL, and the like to the memory device 200. In addition, data DATA to be programmed and the read data DATA may be transmitted/received between the memory controller 100 and the memory device 200.

According to embodiments, the memory device 200 may include a non-volatile memory device. In an example, the memory device 200 may include a non-volatile memory device such as a NAND flash memory, a vertical NAND flash memory, a NOR flash memory, a resistive random access memory, a phase-change memory, and a magnetoresistive random access memory, or the like.

In some embodiments, the memory device 200 or the memory system 10 may be implemented with an embedded memory embedded in an electronic apparatus, or may be implemented as an external memory that is detachable from the electronic apparatus. In an example, the memory device 200 or the memory system 10 may be implemented in various shapes such as an embedded universal flash storage (UFS) memory device, an embedded multi-media card (eMMC), a solid state drive (SSD), an UFS memory card, compact flash (CF), secure digital (SD), micro secure digital (Micro-SD), Mini-SD, extreme digital (xD), a memory stick, and the like.

The memory cell array 210 may include a plurality of cell blocks (also called memory block). In addition, each of the plurality of cell blocks may include a plurality of pages, and each of the plurality of pages may include a plurality of memory cells. In the memory cell array 210, an erasing operation of data may be performed in units of cell blocks, and programming and reading operations of data may be performed in units of at least a part of a page.

According to embodiments, the control logic 230 may control the general operation of the memory device 200 in relation to a memory operation. For example, the control logic 230 may generate an internal control signal for an internal control operation of the memory device 200 based on the control signal from the memory controller 100. To this end, the control logic 230 may be implemented with a micro controller unit (MCU) system.

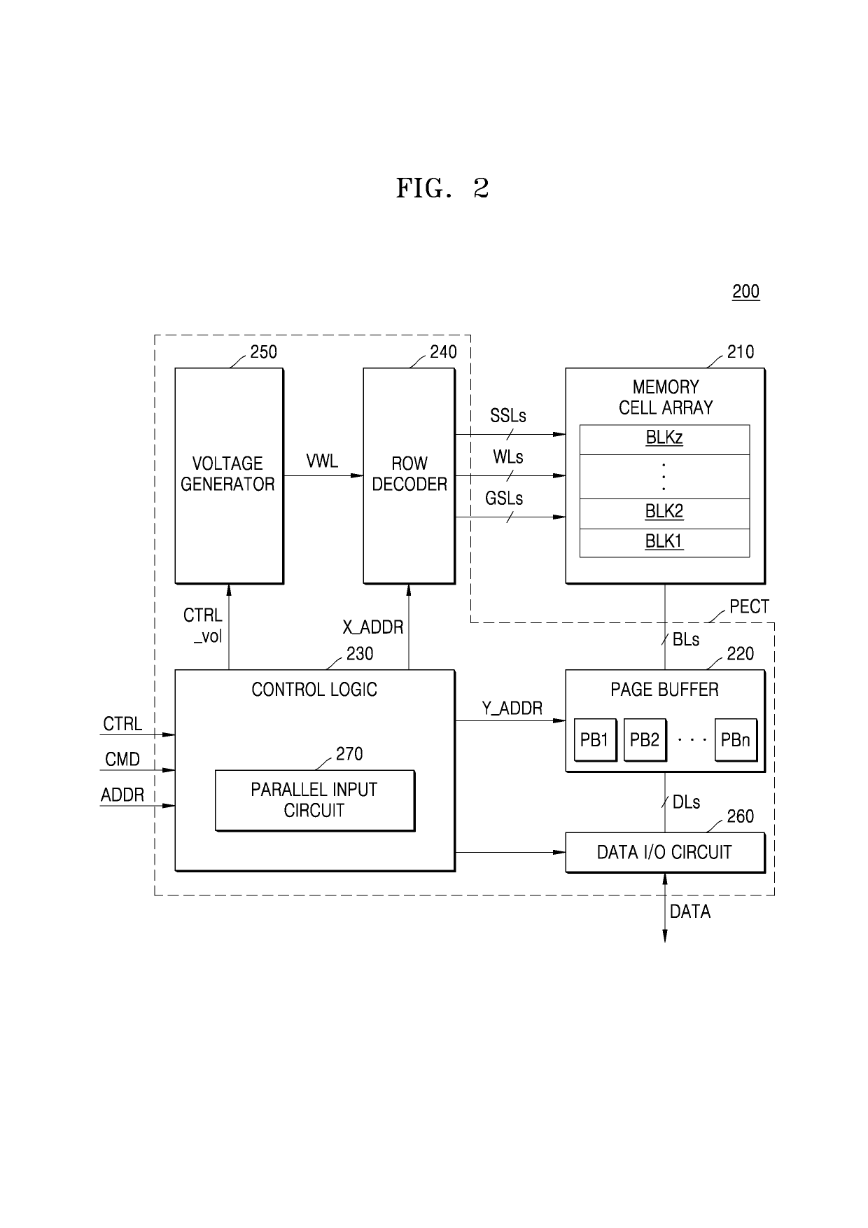

FIG. 2 is a block diagram illustrating the memory device 200 according to an embodiment.

Referring to FIG. 2, the memory device 200 may include the memory cell array 210, the page buffer 220, the control logic 230, a row decoder (e.g., row decoder circuit) 240, a voltage generator (e.g., voltage generation circuit) 250, and a data input/output (I/O) circuit 260.

The memory cell array 210 may include a plurality of memory blocks BLK1 to BLKz, and z is a positive integer. Each of the plurality of memory blocks BLK1 to BLKz may include a plurality of pages, and each of the plurality of pages may include a plurality of memory cells. For example, the memory block may be a unit of erasing, and the page may be a unit of writing and reading. Each memory cell may store one or more bits, and specifically, each memory cell may be used as a single level cell (SLC), a multi-level cell (MLC), a triple level cell (TLC), or a quadruple level cell (QLC).

The memory cell array 210 may be connected to a plurality of word lines WL, a plurality of string selection lines SSL, a plurality of ground selection lines GSL, and a plurality of bit lines BL. The memory cell array 210 may be connected to the row decoder 240 via the plurality of word lines WL, the plurality of string selection lines SSL, the plurality of ground selection lines GSL, and the common source lines CSL, and may be connected to the page buffer 220 via the plurality of bit lines BL.

In an embodiment, the memory cell array 110 may include a three-dimensional memory cell array. The three-dimensional memory cell array may be monolithically formed in an active area in which it is arranged on a silicon substrate, and in at least one physical level of memory cell arrays having a circuit formed on the silicon substrate or in the silicon substrate as a circuit relating to the operation of memory cells. The term “monolithic” may indicate that layers of each level that constitutes the array are stacked directly on layers of each lower level of the array. The three-dimensional memory cell array may include a plurality of cell strings or NAND strings arranged in a vertical direction. Each cell string may include memory cells respectively connected to word lines stacked vertically on the silicon substrate. U.S. Patent Laid-open Publication No. 7,679,133, U.S. Patent Laid-open Publication No. 8,553,466, U.S. Patent Laid-open Publication No. 8,654,587, and U.S. Patent Laid-open Publication No. 8,559,235, and U.S. Patent Application Publication No. 2011/0233648 are incorporated herein by reference in their entireties.

The control logic 230 may output various control signals for writing data into the memory cell array 210, reading the data from the memory cell array 110, or erasing the memory cell array 110 based on the command CMD, the address ADDR, and the control signal CTRL received from the memory controller 100. Thus, the control logic 230 may control various operations in the memory device 100 in general. Specifically, the control logic 230 may provide a voltage control signal CTRL_vol to the voltage generator 250, may provide a row address X_ADDR to the row decoder 240, and may provide a column address Y_ADDR to the page buffer 220.

According to embodiments, the control logic 230 may further include a parallel input circuit 270. The parallel input circuit 270 may be a circuit capable of inputting a setting value to a special function register except for an internal path of the control logic 230 implemented with an MCU system. The parallel input circuit 270 may store the setting value directly in the special function register without using a system bus of the control logic 230. For example, the parallel input circuit 270 may input setting values to special function registers during a single cycle in response to an over-bandwidth event. The over-bandwidth event may correspond to an event in which data exceeding the bandwidth size of the system bus of the control logic 230 are required to be input during a single cycle. For example, the over-bandwidth event may include at least one of initialization of an operation, execution of a reset command, and execution of a suspend command. A detailed description of the parallel input circuit 270 will be provided below.

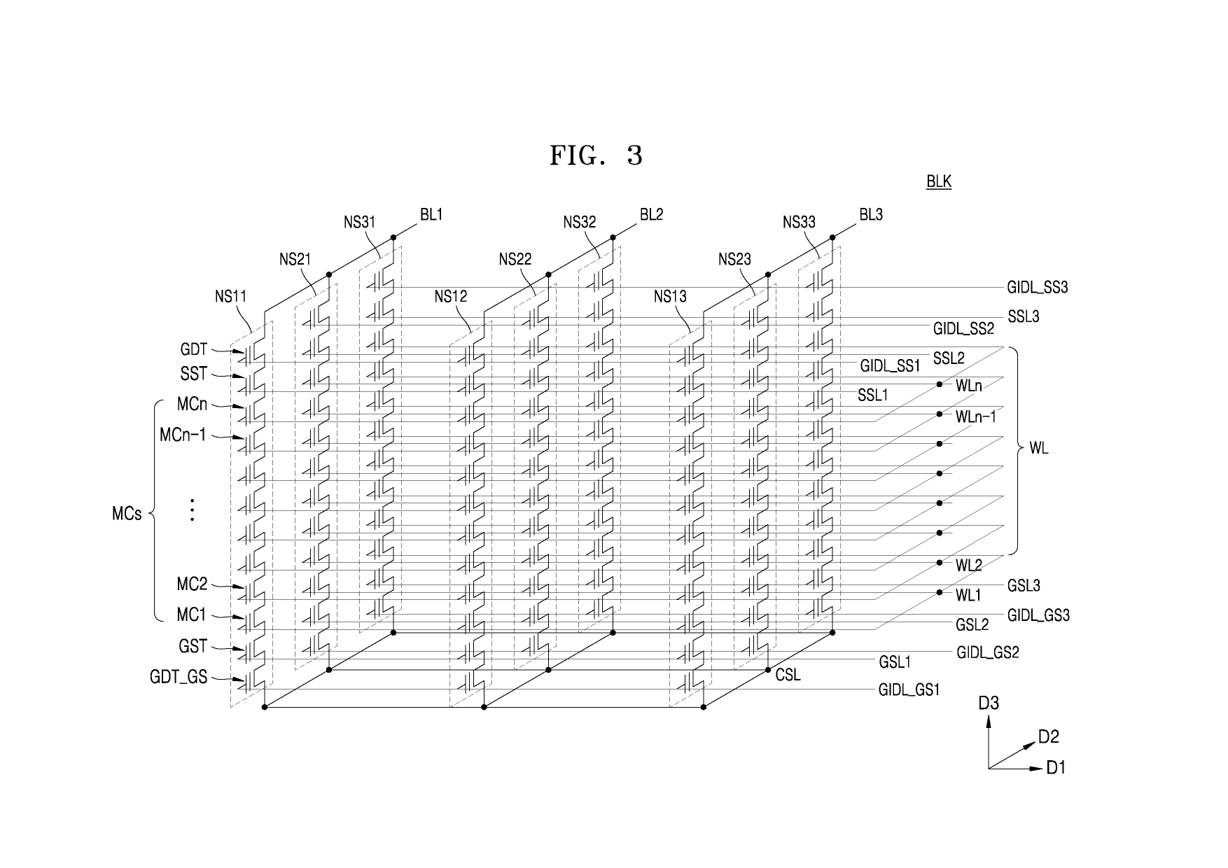

FIG. 3 is a circuit diagram illustrating a memory block according to an embodiment.

Referring to FIG. 3, the memory block BLK may correspond to one of the memory blocks BLK1 to BLKz of FIG. 2. The memory block BLK may include NAND strings NS11 to NS33, and each NAND string (e.g., NS11) may include a string selection transistor SST, a plurality of memory cells MCs, and a ground selection transistor GST, which are connected in series. The transistors SST and GST and the memory cells MCs included in each NAND string may form a stacked structure in a third direction D3 (i.e., a vertical direction) on the substrate.

The word lines WL1 to WL8 may extend in a first direction D1, and the bit lines BL1 to BL3 may extend in a second direction D2. NAND strings NS11, NS21, and NS31 may be placed between the first bit line BL1 and the common source line CSL, NAND strings NS12, NS22, and NS32 may be placed between the second bit line BL2 and the common source line CSL, and NAND strings NS13, NS23, and NS33 may be placed between the third bit line BL3 and the common source line CSL. The string selection transistor SST may be connected to corresponding string selection lines SSL to SSL3. The memory cells MCs may be respectively connected to the corresponding word lines WL1 to WL8. The ground selection transistor GST may be connected to corresponding ground selection lines GSL to GSL3. The string selection transistor SST may be connected to a corresponding bit line, and the ground selection transistor GST may be connected to the common source line CSL. Here, the number of NAND strings, the number of word lines, the number of bit lines, the number of ground selection lines, and the number of string selection lines may be changed variously according to embodiments.

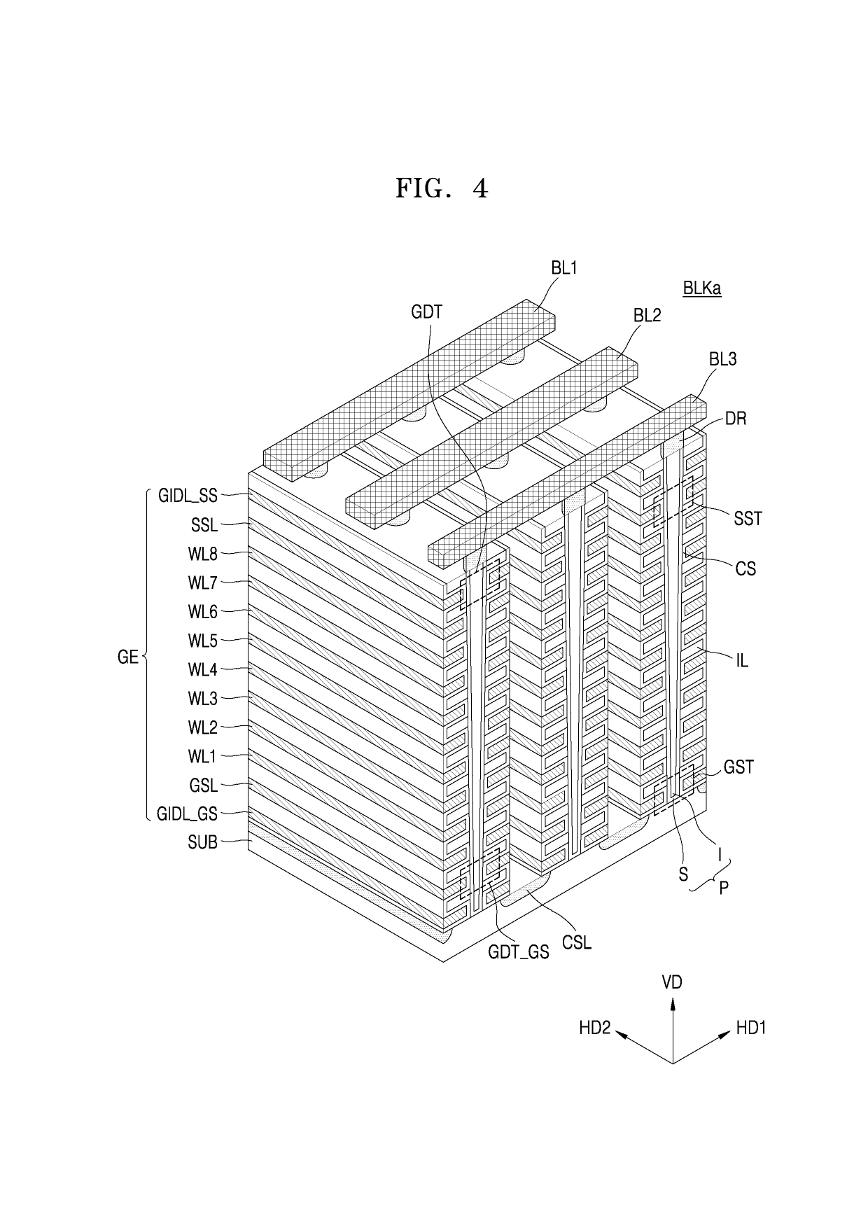

FIG. 4 is a perspective view illustrating a cell block BLK according to an embodiment.

Referring to FIG. 4, the cell block BLK is formed vertically with respect to a substrate SUB. The substrate SUB may have a first conductivity type (e.g., a p type), and the common source line CSL doped with impurities of a second conductivity type (e.g., an n type) is provided to the substrate SUB and may extend in a second horizontal direction HD2 on the substrate SUB. A plurality of insulating layers IL that extends in the second horizontal direction HD2 may be sequentially provided in a vertical direction VD on an area of the substrate SUB between two adjacent common source lines CSL and the plurality of insulating layers IL may be spaced apart from each other by a certain distance in the vertical direction VD. For example, the plurality of insulating layers IL may include an insulating material such as silicon oxide.

A plurality of pillars P may be sequentially arranged in the first horizontal direction HD1 and may penetrate the plurality of insulating layers IL in the vertical direction VD in the area of the substrate SUB between the two adjacent common source lines CSL. For example, the plurality of pillars P may penetrate the plurality of insulating layers IL and may be in contact with the substrate SUB. Specifically, a surface layer S of each pillar P may include a silicon material having a first type and may function as a channel region. An internal layer I of each pillar P may include an insulating material such as silicon oxide, or an air gap.

A charge storage layer CS may be provided along an exposed surface of the insulating layers IL, the pillars P, and the substrate SUB in an area between the two adjacent common source lines CSL. The charge storage layer CS may include a gate insulating layer (or referred to as a ‘tunneling insulating layer’), a charge trap layer, and a blocking insulating layer. For example, the charge storage layer CS may have an oxide-nitride-oxide (ONO) structure. In addition, a gate electrode GE such as the selection lines GSL and SSL and the word lines WL0 to WL7 is provided to the exposed surface of the charge storage layer CS in the area between the two adjacent common source lines CSL.

Drains or drain contacts DR may be respectively provided to the plurality of pillars P. For example, the drains or the drain contacts DR may include a silicon material doped with impurities having a second conductivity type. Bit lines BL1 to BL3 that extend in the first horizontal direction HD1 and are spaced apart from each other by a certain distance in the second horizontal direction HD2 may be provided to the drains DR.

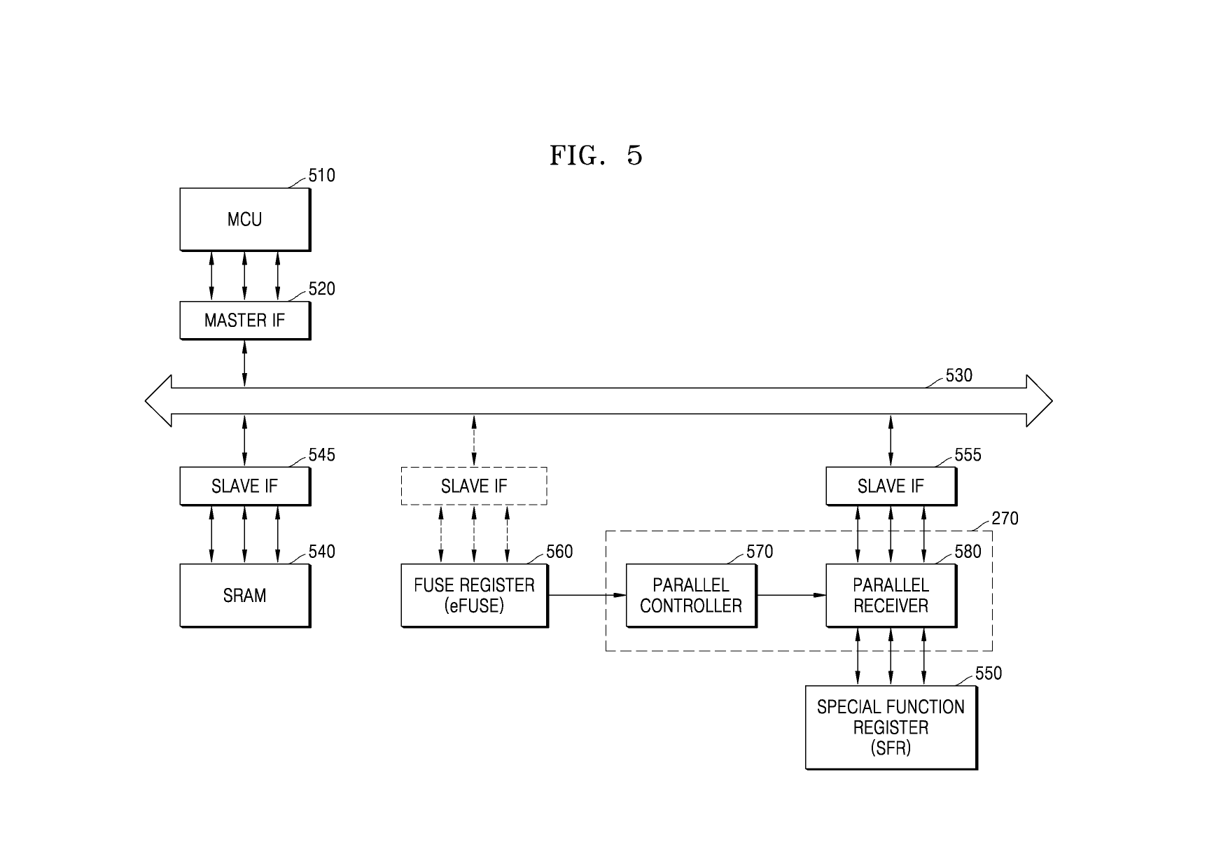

FIG. 5 is a block diagram illustrating an example of a control logic according to an embodiment.

Referring to FIG. 5, the control logic (e.g., the control logic 230 of FIG. 1) may be based on an MCU system. For example, the control logic may include MCU 510, a master interface (IF) 520, a system bus 530, a static random access memory (SRAM) 540, a special function register (SFR) (e.g., special function register circuit) 550, a fuse register (eFUSE) (e.g., fuse register circuit) 560, a plurality of slave IFs 545 and 555, a parallel controller 570, and a parallel receiver 580.

According to embodiments, the microcontroller 510 may control the overall operation relating to a memory operation of the control logic. For example, an internal control signal for an internal control operation of the memory device 200 may be generated. The system bus 530 may provide a data transmission path between the microcontroller 510 and the SFR 550.

The SFR 550 may be a register that monitors and controls the peripheral function of the microcontroller 510. The microcontroller 510 may activate/deactivate a special function by storing a value in the SFR 550 and may identify the activated state of the special function. For example, the microcontroller 510 may identify the activated state of the special function based on the value stored in the SFR 550. The fuse register 560 may be a register that stores a specific setting value defined by a user temporarily.

According to embodiments, the fuse register 560 may transmit the setting value to the SFR 550 via a parallel input circuit (e.g., 270 of FIG. 2) instead of being connected to the system bus 530. The parallel input circuit 270 may include a parallel controller 570 and a parallel receiver 580. That is, in parallel with the microcontroller 510 which transmits the setting value to the SFR 550 via the system bus 530, the setting value of the fuse register 560 may be transmitted to the SFR 550 by bypassing the system bus 530. A detailed description of the parallel controller 570 and the parallel receiver 580 will be provided below.

According to a comparative example, a control logic may not include a parallel controller and parallel receiver. In this case, a microcontroller may read data from a fuse register via a the system bus so as to input a value to an SFR, and may calculate a setting value to be input to the SFR using the read data. Subsequently, the microcontroller may write the calculated setting value into the SFR via the system bus. That is, in order to input a value to the SFR, the system bus may be utilized in a section in which the microcontroller reads the data from the fuse register and in a section in which the microcontroller writes the data into the SFR. Therefore, because it necessarily causes utilization of the system bus, the amount of data that may be transferred per single cycle may be limited to the maximum bus bandwidth at the same address. Because the size of data that may be transmitted during a single cycle is fixed, when an event occurs that requires transmitting a lot of data, a time delay may occur, resulting in time overhead. The event is an event that requires transferring a lot of data to various addresses, and may include, for example, initialization of an operation, execution of a reset command, or execution a suspend command, and embodiments are not limited thereto. The event may be referred to as an over-bandwidth event.

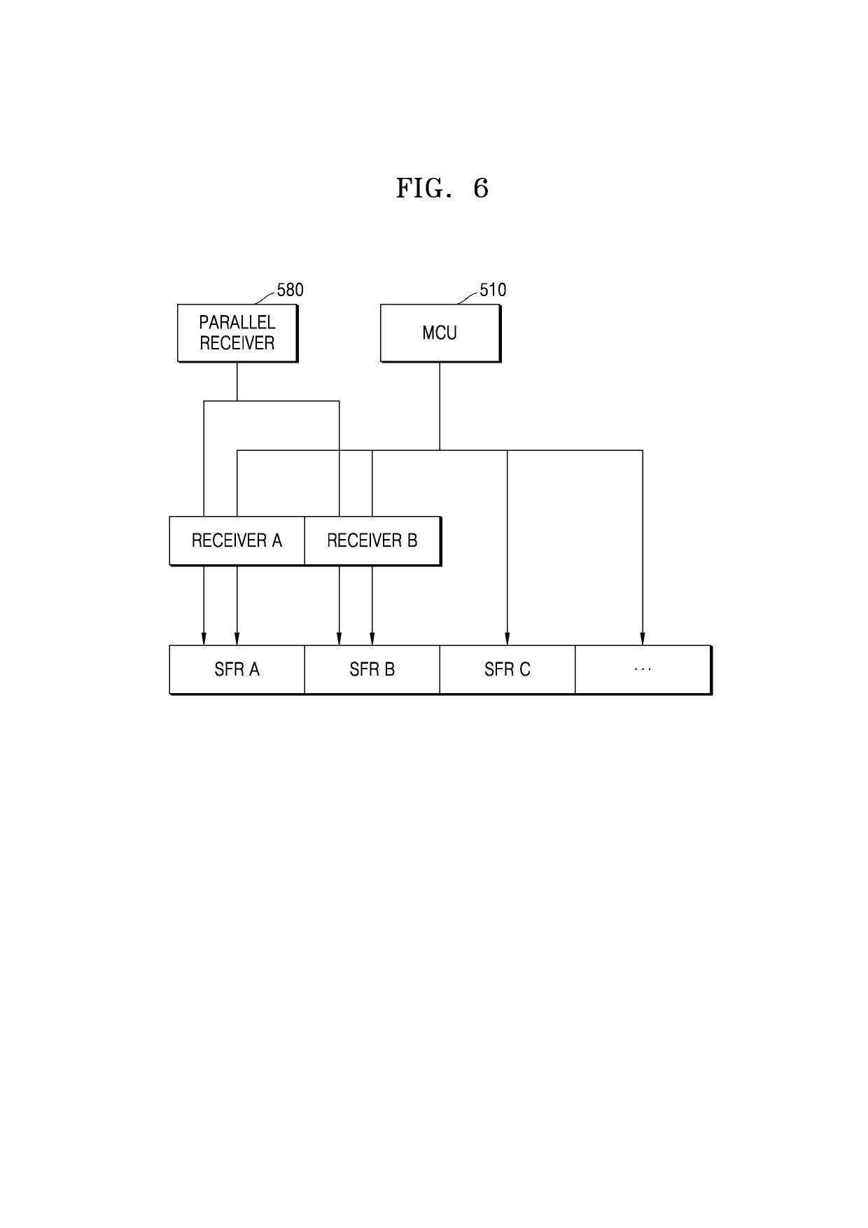

FIG. 6 illustrates an example of a SFR according to an embodiment.

Referring to FIG. 6, the SFR 550 may include a plurality of registers (e.g., a plurality of register circuits). For example, the SFR 550 may include at least a first register SFR A, a second register SFR B, and a third register SFR C.

According to embodiments, the first register SFR A and the second register SFR B may have two paths to which data is input. For example, the first register SFR A and the second register SFR B may be connected to a first path to which a setting value is input from the microcontroller 510, and a second path to which a setting value is input from the parallel controller 570. The third register SFR C and the other registers may be connected only to the first path to which a setting value is input from the microcontroller 510. The first register SFR A and the second register SFR B may be registers that need to be set simultaneously when an operation is initialized, a reset command is executed, or a suspend command is executed. When the setting values are not transmitted to the first register SFR A and the second register SFR B at one time via the second path from the parallel controller 570, performance deterioration may occur because the setting values have to be transmitted over several cycles due to bandwidth limitations of the system bus 530.

According to embodiments, when an over-bandwidth event (e.g., initialization of an operation, execution of a reset command, and execution of a suspend command) in which a large amount of data needs to be transmitted at one time, occurs, the third register SFR C within a single cycle may receive the setting values from the microcontroller 510 via the system bus 530, and the first register SFR A and the second register SFR B may receive the setting values from the parallel controller 570 via the parallel receiver 580. Thus, the first register SFR A and the third register SFR B may receive the setting values within one cycle.

According to embodiments, the parallel receiver (e.g. 580 of FIG. 5) may include a plurality of receivers. The number of a plurality of receivers may be the same as the number of registers connected to both the first path to which the setting value is input from the microcontroller 510 and the second path to which the setting value is input from the parallel controller 570 among SFRs. For example, because the first register SFR A and the second register SFR B are both connected to two paths to which the setting values are input, the parallel receiver 580 may include a first parallel receiver (receiver A) and a second parallel receiver (receiver B).

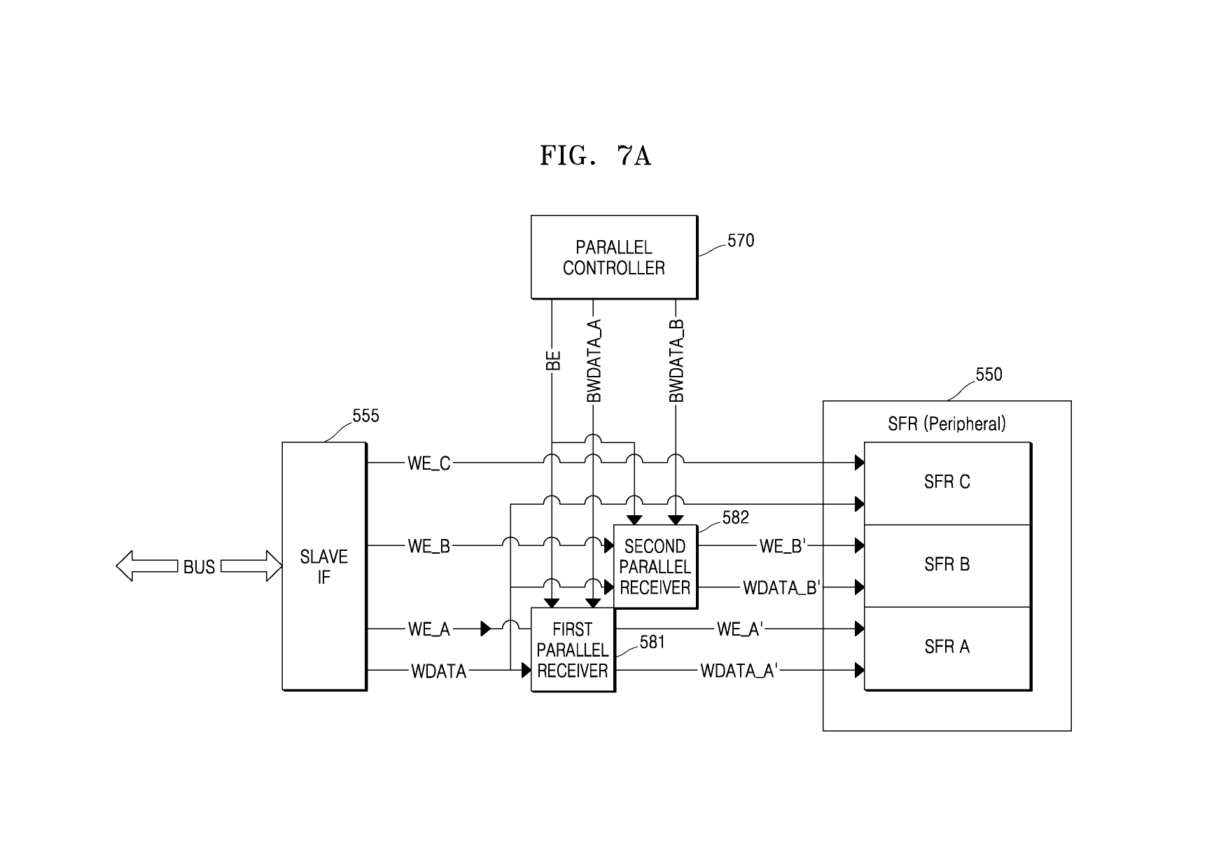

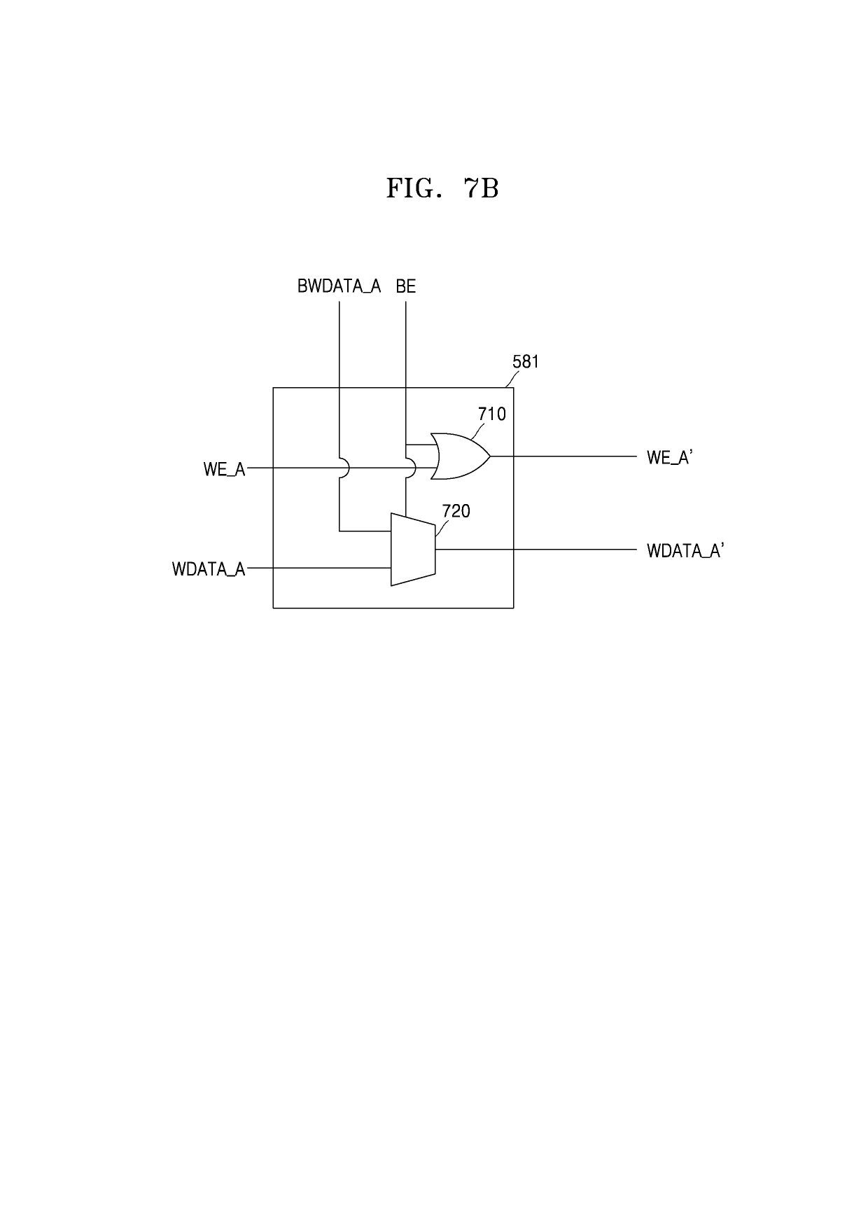

FIG. 7A illustrates an example of signal transmission between a parallel controller and a parallel receiver according to an embodiment.

Referring to FIG. 7A, the parallel controller (e.g., the parallel controller 570 of FIG. 5) may transmit a burst enable signal BE (or may also be referred to as a parallel enable signal) to the parallel receiver (e.g., the parallel receiver 580 of FIG. 5). The burst enable signal BE may be a signal indicating activation of a parallel transmission mode. For example, the burst enable signal BE may be activated in response to the parallel controller receiving the control signal from a memory controller (e.g., 100 of FIG. 1) via a pad of the parallel controller. The parallel transmission mode may be a mode in which data is transmitted to the first register SFR A and the second register SFR B via the parallel receiver 580. For example, the parallel controller 570 may transmit the burst enable signal BE to a first parallel receiver 581 and a second parallel receiver 582.

The parallel controller 570 may transmit burst write data BWDATA_A and BWDATA_B (or may also be referred to as parallel writing data) to the parallel receiver 580 based on logic high of the burst enable signal BE. For example, the parallel controller 570 may transmit first burst data write data BWDATA_A to the first parallel receiver 581 and the second bust write data BWDATA_B to the second parallel receiver 582. The first burst write data BWDATA_A and the second burst write data BWDATA_B may be simultaneously transmitted.

A slave IF (e.g., the slave IF 555 of FIG. 5) may receive write data WDATA and an address from the microcontroller 510 via a bus (e.g., the system bus 530 of FIG. 5). The slave IF 555 may further include a decoder (e.g., decoder circuit). The slave IF 555 may identify a target SFR by decoding the address received using the decoder. For example, in a normal transmission mode, the slave IF 555 may identify that the target SFR is the first register SFR A to the third register SFR C by decoding the address. Subsequently, the slave IF 555 may sequentially generate and transmit write enable signals WE for the first register SFR A to the third register SFR C. For example, the slave IF 555 may generate and transmit a write enable signal WE_A for the first register SFR A in a first cycle. In this case, the first register SFR A may be connected to each of a first path to which a setting value is input from the microcontroller 510, and a second path to which the setting value is input from the parallel controller 570. Thus, the first register SFR A may be connected to a corresponding first parallel receiver 581. The write enable signal WE_A for the first register SFR A may be transmitted to the first register SFR A via the first parallel receiver 581.

In a second cycle that is a next cycle of the first cycle, the slave IF 555 may generate and transmit a write enable signal WE_B for the second register SFR B. In this case, the second register SFR B may be connected to each of a first path to which a setting value is input from the microcontroller 510, and a second path to which the setting value is input from the parallel controller 570. Thus, the second register SFR B may be connected to a corresponding second parallel receiver 582. The write enable signal WE_B for the second register SFR B may be transmitted to the second register SFR B via the second parallel receiver 582.

In a third cycle that is a next cycle, the slave IF 555 may generate and transmit a write enable signal WE_C for the third register SFR C. Unlike the first register SFR A and the second register SFR B, the third register SFR C may be connected only to the first path to which the setting value is input from the microcontroller 510. Thus, a parallel receiver that corresponds to the third register SFR C does not exist, and the third register SFR C may receive the write data WDATA and the write enable signal WE_C for the third register SFR C directly from the slave IF 555. That is, the setting value may be input to the third register SFR C only from the microcontroller 510.

The first parallel receiver 581 may selectively transmit one of data from the microcontroller 510 and data from the slave IF 555 to the first register SFR A. For example, when the burst enable signal BE is transited to logic high, the first parallel receiver 581 may transmit first burst write data BWDATA_A as first output data WDATA_A’ to the first register SFR A. When the burst enable signal BE is at logic low, the first parallel receiver 581 may transmit the write data WDATA received from the slave IF 555 as the first output data WDATA_A’ to the first register SFR A.

The second parallel receiver 582 may selectively transmit one of data from the microcontroller 510 and data from the slave IF 555 to the second register SFR B. For example, when the burst enable signal BE is transited to logic high, the second parallel receiver 582 may transmit second burst write data BWDATA_B as second output data WDATA_B’ to the second register SFR B. When the burst enable signal BE is at logic low, the second parallel receiver 582 may transmit the write data WDATA received from the slave IF 555 as the second output data WDATA_B’ to the second register SFR B.

Referring to FIG. 7B together, an internal block of the first parallel receiver 581 is shown. It will be appreciated that an internal block of the second parallel receiver 582 may be implemented in the same manner as the first parallel receiver 581.

The first parallel receiver 581 may include an OR gate 710 and a multiplexer (MUX) 720. The OR gate 710 may transmit a final write enable signal WE_A’ to the first register SFR A in response to one of the burst enable signal BE and the write enable signal WE_A for the first register SFR A being at logic high. That is, the OR gate 710 may generate and transmit the final write enable signal WE_A’ so as to input a setting value to the first register SFR A depending on activation of one of the write enable signal WE_A for the first register SFR A activated in a normal transmission mode and the burst enable signal BE activated in response to a parallel transmission mode.

The MUX 720 may output one of the first write data WDATA_A and the first burst write data BWDATA_A to the first register SFR A based on the burst enable signal BE. For example, when receiving the burst enable signal BE at logic high, the MUX 720 may output the first burst write data BWDATA_A to the first register SFR A, and when receiving the burst enable signal BE at logic low, the MUX 720 may output the first write data WDATA_A to the first register SFR A.

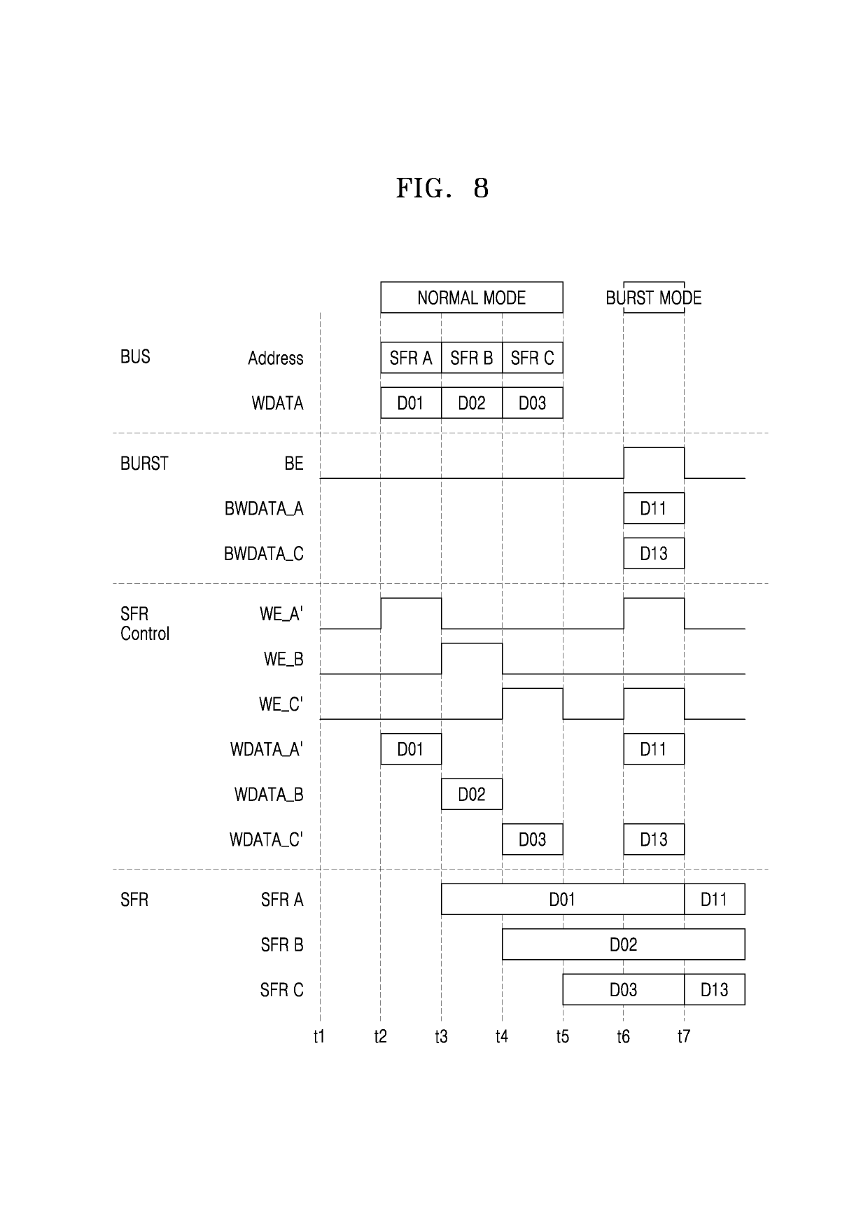

FIG. 8 illustrates an example of a signal time line according to an embodiment.

Referring to FIG. 8, a memory device 200 may operate in a normal transmission mode and then may switch to a parallel transmission mode. The interval from time t1 to time t7 may correspond to a single clock cycle.

At time t2, the memory device 200 may operate in the normal transmission mode. Because the memory device 200 operates in the normal transmission mode from time t2 to time t5, the burst enable signal BE may be at logic low.

At time t2, the slave IF 555 may receive an address and write data via the system bus 530. The write data may be a setting value for each SFR 550. The slave IF 555 may identify a target SFR by decoding the address. For example, the slave IF 555 may identify that the target SFR is sequentially the first register SFR A, the second register SFR B and the third register SFR C, by decoding the address. The first register SFR A and the third register SFR C may be SFRs connected to the parallel input circuit (e.g., 270 of FIG. 2), and the second register SFR B may be an SFR connected only to the microcontroller 510.

The slave IF 555 may write data into each SFR in each cycle from time t2. For example, during one cycle from time t2 to time t3, the slave IF 555 may transmit the first write enable signal WE_A and the first write data WDATA_A to the first parallel receiver 581, and the first parallel receiver 581 may apply the first final write enable signal WE_A’ to the first register SFR A and may input the first final write data WDATA_A’ to the first register SFR A. Referring to FIG. 7B together, the first final write enable signal WE_A’ may be an output signal of the OR gate 710 to which the first write enable signal WE_A at logic high and the burst enable signal BE at logic low are input. The first final write data WDATA_A’ may be an output signal of the MUX 720 based on the burst enable signal BE at logic low. Subsequently, during one cycle from time t3 to time t4, the slave IF 555 may apply the write enable signal WE_B to the second register SFR B and apply the second write data WDATA_B to the second register SFR B. Because the second register SFR B is an SFR connected only to the microcontroller 510, the second register SFR B may receive the second write enable signal WE_B and the second write data WDATA_B from the slave IF 555.

During one cycle from time t4 to time t5, the slave IF 555 may transmit the third write enable signal WE_C and the third write data WDATA_C to a third parallel receiver, and the third parallel receiver may apply a third final write enable signal WE_C’ to the third register SFR and may input the third final write data WDATA_C’ to the third register SFR C. That is, in the normal transmission mode, it may be confirmed that data is input to a SFR in each cycle.

At time t6, the memory device 200 may operate in the parallel transmission mode. For example, the microcontroller 510 may transmit an address and write data directly to the parallel controller 570 via the fuse register 560 without transmitting the address and the write data to the slave IF 555 in response to detection of an event such as initialization of an operation, execution of a reset command, or execution of a suspend command. The parallel controller 570 may transit the burst enable signal for parallel transmission into logic high in response to transmission of the address and the write data.

The parallel controller 570 may write data into each SFR in parallel during one cycle of time t6 to time t7. For example, during one cycle, the parallel controller 570 may transmit the burst enable signal BE and the first burst write data BWDATA_A to the first parallel receiver 581, and the first parallel receiver 581 may apply the first final write enable signal WE_A’ to the first register SFR A and may input the first final write data WDATA_A’ to the first register SFR A. Referring to FIGS. 7B and 8, the first final write enable signal WE_A’ may be an output signal of the OR gate 710 to which the first write enable signal WE_A at logic low and the burst enable signal BE at logic high are input. The first final write data WDATA_A’ may be an output signal of the MUX 720 for outputting the first burst write data BWDATA_A based on the burst enable signal BE at logic high.

The parallel controller 570 may transmit the burst enable signal BE and the third burst write data BWDATA_C to a third parallel receiver, and the third parallel receiver may apply a third final write enable signal WE_C’ to the third register SFR C and may input the third final write data WDATA_C’ to the third register SFR C. Referring to FIG. 7B together, the third final write enable signal WE_C’ may be an output signal of the OR gate 710 to which the third write enable signal WE_C at logic low and the burst enable signal BE at logic high are input. The third final write data WDATA_C’ may be an output signal of the MUX 720 for outputting the third burst write data BWDATA_C based on the burst enable signal BE at logic high.

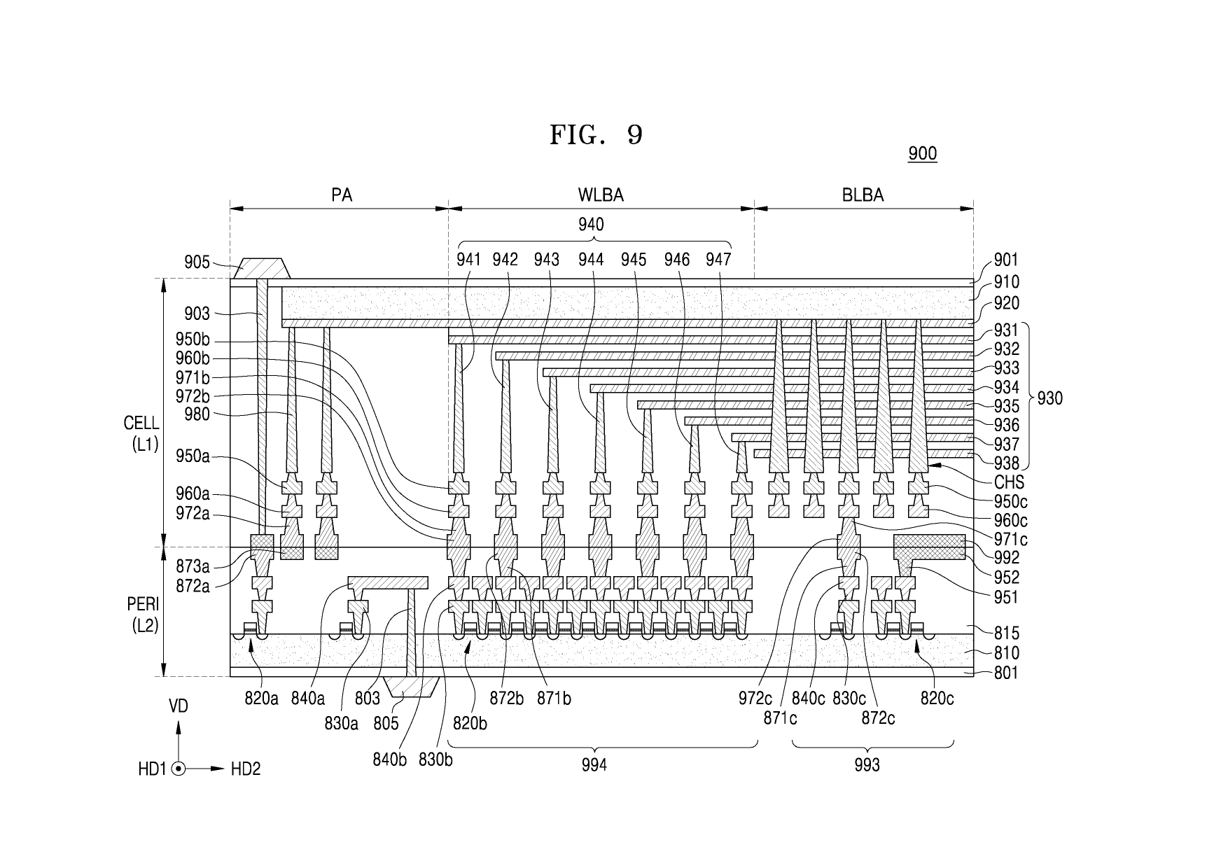

FIG. 9 is a cross-sectional view illustrating a memory device 900 having a B-VNAND structure according to an embodiment.

When a non-volatile memory included in a memory device is implemented with a flash memory of a B-VNAND type, the non-volatile memory may have a structure shown in FIG. 9.

Referring to FIG. 9, a cell region CELL of the memory device 900 may correspond to a first semiconductor layer L1, and a peripheral circuit region PERI may correspond to a second semiconductor layer L2. Each of the peripheral circuit region PERI and the cell region CELL of the memory device 900 may include an external pad bonding area PA, a word line bonding area WLBA, and a bit line bonding area BLBA. For example, the plurality of word lines WL, the plurality of string selection lines SSL, the plurality of ground selection lines GSL, and the memory cell array 110 of FIG. 2 may be formed in the first semiconductor layer L1, and the control logic circuit 120, the pager buffer circuit 140, the voltage generator 150, and the row decoder 130 may be formed in the second semiconductor layer L2.

The memory device 900 may have a chip to chip (C2C) structure. The C2C structure may refer to manufacturing an upper chip including the cell region CELL on a first wafer and manufacturing a lower chip including the peripheral circuit region PERI on a different second wafer from the first water and then connecting the upper chip and the lower chip to each other using a bonding method. For example, the bonding method may indicate a method of electrically connecting a bonding metal formed on an uppermost metal layer of the upper chip and a bonding metal formed on an uppermost metal layer of the lower chip to each other. For example, when the bonding metal is formed of copper (Cu), the bonding method may be a Cu-Cu bonding method. In another embodiment, the bonding metal may also be formed of aluminum (Al) or tungsten (W) as well as Cu.

The peripheral circuit region PERI may include a first substrate 810, an interlayer insulating layer 815, a plurality of circuit elements 820a, 820b, and 820c formed on the first substrate 810, first metal layers 830a, 830b, and 830c respectively connected to the plurality of circuit elements 820a, 820b, and 820c, and second metal layers 840a, 840b, and 840c formed on the first metal layers 830a, 830b, and 830c. In an embodiment, the first metal layers 830a, 830b, and 830c may be formed of W having a relatively high resistance, and the second metal layers 840a, 840b, and 840c may be formed of Cu having a relatively low resistance.

The first metal layers 830a, 830b, and 830c and the second metal layers 840a, 840b, and 840c are shown, however, embodiments are not limited thereto, and at least one metal layer may be further formed on the second metal layers 840a, 840b, and 840c. At least a part of one or more metal layers formed on the first metal layers 830a, 830b, and 830c may be formed of Al having a lower resistance than Cu forming the second metal layers 840a, 840b, and 840c.

The interlayer insulating layer 815 may be arranged on the first substrate 810 so as to cover the plurality of circuit elements 820a, 820b, and 820c, the first metal layers 830a, 830b, and 830c, and the second metal layers 840a, 840b, and 840c and may include an insulating material such as silicon oxide, silicon nitride or the like. Lower bonding metals 871b and 872b may be formed on the second metal layer 840b of the word line bonding area WLBA. In the word line bonding area WLBA, the lower bonding metals 871b and 872b of the peripheral circuit region PERI may be electrically connected to the upper bonding metals 971b and 972b of the cell region CELL using a bonding method, and the lower bonding metals 871b and 872b and the upper bonding metals 971b and 972b may be formed of aluminum, copper, tungsten or the like.

The cell region CELL may provide at least one memory block. The cell region CELL may include a second substrate 910 and a common source line 920. A plurality of word lines 930(931 to 938) may be stacked on the second substrate 910 in a vertical direction VD with respect to an upper surface of the second substrate 910. String selection lines and ground selection lines may be arranged on each of an upper portion and a lower portion of the word lines 930, and a plurality of word lines 930 may be arranged between the string selection lines and the ground selection lines.

In the bit line bonding area BLBA, a channel structure CHS may extend in a direction perpendicular to the upper surface of the second substrate 910 and may penetrate the word lines 930, the string selection lines, and the ground selection lines. The channel structure CHS may include a data storing layer, a channel layer, and a buried insulating layer, and the channel layer may be electrically connected to a first metal layer 950c and a second metal layer 960c. For example, the first metal layer 950c may be a bit line contact, and the second metal layer 960c may be a bit line. In an embodiment, the bit line 960c may extend in a second horizontal direction HD2 in parallel to the upper surface of the second substrate 910.

In an embodiment, an area in which the channel structure CHS and the bit line 960c are arranged, may be defined as the bit line bonding area BLBA. The bit line 960c may be electrically connected to the circuit elements 820c for providing the page buffer 993 of the peripheral circuit region PERI in the bit line bonding area BLBA. For example, the bit line 960c may be connected to the upper bonding metals 971c and 972c of the cell region CELL, and the upper bonding metals 971c and 972c may be connected to the lower bonding metals 871c and 872c connected to the circuit elements 820c of the page buffer 993. Thus, the page buffer 993 may be connected to the bit line 960c through the bonding metals 971c, 972c, 871c, and 872c.

In an embodiment, the memory device 900 may further include a through electrode THV disposed in the bit line bonding area BLBA. The through electrode THV may penetrate the word lines 930 and extend in the vertical direction VD. The through electrode THV may be connected to the common source line 920 and/or the second substrate 910. An insulating ring may be arranged in the periphery of the through electrode THV, and the through electrode THV may be insulated from the word lines 930. The through electrode THV may be connected to the peripheral circuit region PERI through the upper bonding metal 972b and the lower bonding metal 872b.

In the word line bonding area WLBA, the word lines 930 may extend in the second horizontal direction HD2 in parallel to the upper surface of the second substrate 910 and may be connected to the plurality of cell contact plugs 941 to 947; 940. The word lines 930 and the cell contact plugs 940 may be connected to each other in pads in which at least a part of the word lines 930 extends to different lengths in the vertical direction VD. A first metal layer 950b and a second metal layer 960b may be sequentially connected to each other at an upper portion of the cell contact plugs 940 connected to the word lines 930. The cell contact plugs 940 may be connected to the peripheral circuit region PERI through the upper bonding metals 971b and 972b of the cell region CELL and the lower bonding metals 871b and 872b in the word line bonding area WLBA.

The cell contact plugs 940 may be electrically connected to the circuit elements 820b providing the row decoder 994 in the peripheral circuit region PERI. In an embodiment, the operating voltage of the circuit elements 820b providing the row decoder 994 may be different from the operating voltage of the circuit elements 820c providing the page buffer 993. For example, the operating voltage of the circuit elements 820c providing the page buffer 993 may be greater than the operating voltage of the circuit elements 820b providing the row decoder 994.

A common source line contact plug 980 may be arranged in an external pad bonding area PA. The common source line contact plug 980 may be formed of a conductive material such as metal, metal compounds, or polysilicon, and may be electrically connected to the common source line 920. A first metal layer 950a and a second metal layer 960a may be sequentially stacked in the upper portion of the common source line contact plug 980. For example, an area in which the common source line contact plug 980, the first metal layer 950a and the second metal layer 960a are arranged, may be defined as the external pad bonding area PA.

Input/output pads 905 and 805 may be arranged in the external pad bonding area PA. A lower insulating layer 801 that covers a lower surface of the first substrate 810 may be formed at a lower portion of the first substrate 810, and the first input/output pad 805 may be formed on the lower insulating layer 801. The input/output pad 805 may be connected to at least one of the plurality of circuit elements 820a, 820b, and 820c arranged in the peripheral circuit region PERI through the first input/output contact plug 803, and may be separated from the first substrate 810 by the lower insulating layer 801. In addition, a side insulating layer may be arranged between the first input/output contact plug 803 and the first substrate 810 so that the first input/output contact plug 803 and the first substrate 810 may be electrically separated from each other.

An upper insulating layer 901 that covers a lower surface of the second substrate 910 may be formed at an upper portion of the second substrate 910, and the second input/output pad 905 may be formed on the upper insulating layer 901. The second input/output pad 905 may be connected to at least one of the plurality of circuit elements 820a, 820b, and 820c arranged in the peripheral circuit region PERI through the second input/output contact plug 903.

According to embodiments, the second substrate 910 and the common source line 920 may not be arranged in an area in which the second input/output contact plug 903 is arranged. In addition, the second input/output pad 904 may not overlap the word lines 930 in a third direction (Z-axis direction). The second input/output contact plug 903 may be separated from the second substrate 910 in a direction in parallel to the upper surface of the second substrate 910, may penetrate an interlayer insulating layer of the cell region CELL and may be connected to the second input/output pad 905.

According to embodiments, the first input/output pad 805 and the second input/output pad 905 may be selectively formed. For example, the memory device 900 may include only the first input/output pad 805 arranged at the upper portion of the first substrate 810 or may include only the second input/output pad 905 arranged at the upper portion of the second substrate 910. Alternatively, the memory device 900 may include all of the first input/output pad 805 and the second input/output pad 905. Metal patterns of an uppermost metal layer may exist as dummy patterns, or the uppermost metal layer may be empty in each of the external pad bonding area PA and the bit line bonding area BLBA included in each of the cell region CELL and the peripheral circuit region PERI.

In the external pad bonding area PA, the memory device 900 may form a lower metal pattern 873a having the same shape as the upper metal pattern 972a in the uppermost metal layer of the peripheral circuit region PERI in response to the upper metal pattern 972a formed in the uppermost metal layer of the cell region CEL. The lower metal pattern 873a formed in the uppermost metal layer of the peripheral circuit region PERI may not be connected to an additional contact in the peripheral circuit region PERI. Similarly, in the external pad bonding area PA, an upper metal pattern having the same shape as the lower metal pattern of the peripheral circuit region PERI may also be formed in an upper metal layer of the cell region CELL in response to the lower metal pattern formed in the uppermost metal layer of the peripheral circuit region PERI.

Lower bonding metals 871b and 872b may be formed on the second metal layer 840b of the word line bonding area WLBA. In the word line bonding area WLBA, the lower bonding metals 871b and 872b of the peripheral circuit region PERI may be electrically connected to the upper bonding metals 971b and 972b of the cell region CELL using a bonding method.

In addition, in the bit line bonding area BLBA, an upper metal pattern 992 having the same shape as the lower metal pattern 952 may be formed in the uppermost metal layer of the cell region CELL in response to the lower metal pattern 952 formed in the uppermost metal layer of the peripheral circuit region PERI. No contacts may be formed on the upper metal pattern 992 formed in the uppermost metal layer of the cell region CELL.

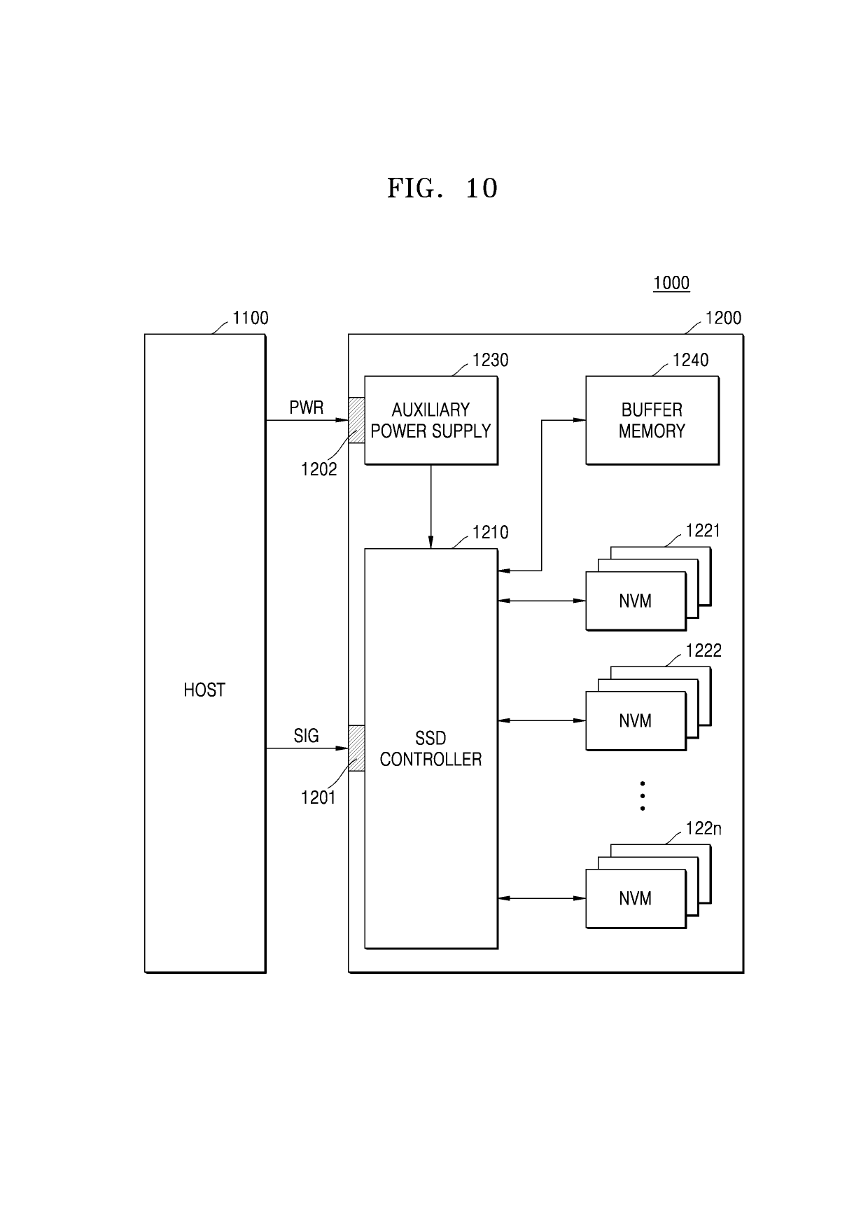

FIG. 10 is a block diagram illustrating a solid state drive (SSD) system according to an embodiment.

A SSD system 1000 may be provided in a data center including several tens of host machines or servers providing several hundreds of virtual machines. For example, the SSD system 1000 may be a computing device such as a laptop computer, a desktop computer, a server computer, a workstation, a portable communication terminal, a personal digital assistant (PDA), a portable multimedia player (PMP), a smartphone, a tablet personal computer (PC), or the like, a virtual machine or a virtual computing device thereof. Alternatively, the SSD system 1000 may be a part of components included in a computing system such as a graphics card. The SSD system 1000 is not limited to a hardware configuration to be described below, and may have other configurations.

Referring to FIG. 10, the SSD system 1000 may include a host 1110 and an SSD 1200.

The host 1100 may be a data processing device that may process data. The host 1100 may execute an operating system (OS) and/or various applications. The host 1100 may include a central processing unit (CPU), a graphics processing unit (GPU), a neural processing unit (NPU), a digital signal processor (DSP), a microprocessor or an application processor (AP), or the like. In an embodiment, the SSD system 1000 may be included in the mobile device, and the host 1100 may be implemented as an AP. In an embodiment, the host 1100 may be implemented as a system-on-a-chip (SoC) and thus may be embedded in the SSD system 1000. The host 1100 may include one or more processors. The host 1100 may include a multi-core processor.

The host 1100 may be configured to execute one or more machine-executable instructions or pieces of software, firmware, or a combination thereof. The host 1100 may control a data processing operation on the SSD 1200. For example, the host 1100 may control a data reading operation, a programming operation, an erasing operation, and a correction operation on an erased cell of the SSD 1200.

The host 1100 may communicate with the SSD 1200 using various protocols. For example, the host 1100 may communicate with the SSD 1200 using an interface protocol such as peripheral component interconnect-express (PCI-E), advanced technology attachment (ATA), serial ATA (SATA), parallel ATA (PATA) or serial attached SCSI (SAS). In addition, other various interface protocols such as a universal flash storage (UFS), a universal serial bus (USB), a multi-media card (MMC), an enhanced small disk interface (ESDI) or an integrated drive electronics (IED) may be applied to a protocol between the host 1100 and the SSD 1200.

The SSD 1200 may exchange signals from the host 1100 via a signal connector and may receive power from a power connector. The SSD 1200 may include an SSD controller 1210, memory devices 1221, 1222, and 122n, an auxiliary power supply 1230, and buffer memory 1240. The memory devices 1221, 1222, and 122n may be vertical stack-type NAND flash memory devices. In this case, the SSD 1200 may be implemented using the above-described embodiments with reference to FIGS. 1 through 9.

While aspects of example embodiments have been particularly shown and described, it will be understood that various changes in form and details may be made therein without departing from the spirit and scope of the following claims.

What is claimed is:

1. A memory device comprising:
a memory cell array comprising a plurality of non-volatile memory cells; and
a control logic circuit comprising:
a system bus;
a microcontroller configured to write data into a plurality of special function registers via the system bus; and
a parallel controller configured to write parallel data into at least two registers among the plurality of special function registers independently of the system bus.

2. The memory device of claim 1, wherein the control logic circuit further comprises:
a slave interface configured to receive an address and write data from the system bus; and
parallel receivers configured to transmit one of the parallel data received from the parallel controller and the write data received from the slave interface to the at least two registers, based on a control signal indicating a parallel transmission mode.

3. The memory device of claim 2, wherein at least one of the parallel receivers comprises:
an OR gate configured to receive the control signal indicating the parallel transmission mode from the parallel controller, receive a write enable signal from the slave interface, and output a final write enable signal; and
a multiplexer configured to selectively output one of the parallel data received from the parallel controller and the data received from the microcontroller.

4. The memory device of claim 2, wherein the parallel controller is further configured to write the parallel data into the at least two registers during a single cycle based on the parallel transmission mode.

5. The memory device of claim 1, further comprising a column decoder circuit, a row decoder circuit, a voltage generation circuit, and a page buffer circuit,
wherein the control logic circuit further comprises a fuse register configured to store configuration values for an operation of the column decoder circuit, the row decoder circuit, and the voltage generation circuit.

6. The memory device of claim 5, wherein the parallel controller is further configured to receive the configuration values from the fuse register and write the configuration values as the parallel data into the at least two registers.

7. The memory device of claim 1, wherein the parallel controller is further configured to generate a control signal indicating a parallel transmission mode in response to an over-bandwidth event, and
wherein the over-bandwidth event comprises any one or any combination of initialization of an operation, execution of a reset command, and execution of a suspend command.

8. A memory system comprising:
a memory controller; and
a memory device comprising:
a plurality of non-volatile memory cells; and
a control logic circuit,
wherein the control logic circuit comprises:
a system bus;
a microcontroller configured to write data into a plurality of special function registers via the system bus; and
a parallel controller configured to write parallel data into at least two registers among the plurality of special function registers in parallel with the system bus.

9. The memory system of claim 8, wherein the control logic circuit further comprises:
a slave interface configured to receive an address and write data from the system bus; and
parallel receivers configured to transmit one of the parallel data received from the parallel controller and the write data received from the slave interface to the at least two registers, based on a control signal indicating a parallel transmission mode.

10. The memory system of claim 9, wherein at least one of the parallel receivers comprises:
an OR gate configured to receive the control signal indicating the parallel transmission mode from the parallel controller, receive a write enable signal from the slave interface, and output a final write enable signal; and
a multiplexer configured to selectively output one of the parallel data received from the parallel controller and the data received from the microcontroller.

11. The memory system of claim 9, wherein the parallel controller is further configured to write the parallel data into the at least two registers during a single cycle based on the parallel transmission mode.

12. The memory system of claim 8, wherein the memory device further comprises a column decoder circuit, a row decoder circuit, a voltage generation circuit, and a page buffer circuit, and
wherein the control logic circuit further comprises a fuse register configured to store configuration values for an operation of the column decoder circuit, the row decoder circuit, and the voltage generation circuit.

13. The memory system of claim 12, wherein the parallel controller is further configured to receive the configuration values from the fuse register and write the configuration values as the parallel data into the at least two registers.

14. The memory system of claim 8, wherein the parallel controller is further configured to generate a control signal indicating a parallel transmission mode in response to an over-bandwidth event, and the over-bandwidth event comprises any one or any combination of initialization of an operation, execution of a reset command, and execution of a suspend command.

15. A control logic comprising:
a system bus;
a plurality of special function registers;
a microcontroller configured to write data into the plurality of special function registers via the system bus; and
a parallel controller configured to write parallel data into at least two registers among the plurality of special function registers independently of the system bus.

16. The control logic of claim 15, further comprising:
a slave interface configured to receive an address and write data from the system bus; and
parallel receiver circuits configured to transmit one of the parallel data received from the parallel controller and the write data received from the slave interface to the at least two registers, based on a control signal indicating a parallel transmission mode.

17. The control logic of claim 16, wherein at least one of the parallel receiver circuits comprises:
an OR gate configured to receive the control signal indicating the parallel transmission mode from the parallel controller, receive a write enable signal from the slave interface, and output a final write enable signal; and
a multiplexer configured to selectively output one of the parallel data received from the parallel controller and the data received from the microcontroller.

18. The control logic of claim 16, wherein the parallel controller is further configured to write the parallel data into the at least two registers during a single cycle based on the parallel transmission mode.

19. The control logic of claim 15, further comprising a fuse register configured to store setting values for an operation of a column decoder, a row decoder, and a voltage generator,
wherein the parallel controller is further configured to receive the setting values from the fuse register and write the setting values as the parallel data into the at least two registers.

20. The control logic of claim 15, wherein the parallel controller is further configured to generate a control signal indicating a parallel transmission mode in response to an over-bandwidth event, and
wherein the over-bandwidth event comprises any one or any combination of initialization of an operation, execution of a reset command, and execution of a suspend command.
